(19) United States
(12) Patent Application Publication
(10) Pub. No.: US 2012/0073619 A1
(43) Pub. Date: Mar. 29, 2012

(54) TEMPERATURE PROTECTION OF A THERMOELECTRIC MODULE AND/OR OF A THERMOELECTRIC GENERATOR USING PHASE CHANGE MATERIALS

(75) Inventor: Jürgen Moors, Neustadt (DE)

(73) Assignee: BASF SE, Ludwigshafen (DE)

(21) Appl. No.: 13/237,592

(22) Filed: Sep. 20, 2011

Related U.S. Application Data
(60) Provisional application No. 61/385,568, filed on Sep. 23, 2010.

(51) Int. Cl. H01L 35/30; H01L 35/34; H01L 35/04

(52) U.S. Cl. 136/201; 136/230; 136/232

(57) ABSTRACT

In a thermoelectric generator (30) a layer (48) of a phase change material is introduced between a pipe (32), which conducts an offgas, and at least one thermoelectric module (40). This phase change material layer stores excess heat Q_{E} at excessively high offgas temperatures and thus protects the thermoelectric modules (40) and at the same time keeps the thermoelectric generator (30) at a constant temperature level, thus improving the efficiency thereof.

The invention relates to a thermoelectric generator comprising at least one pipe which conducts a hot medium, and at least one thermoelectric module.

Offgas heat, for example from power plants or motor vehicles, is frequently released to the environment unutilized. Effective use of this heat would, however, result in higher efficiency.

One means of utilizing this offgas heat is thermoelectric generators (TEGs), which, due to the Seebeck effect, sometimes also referred to as the thermoelectric effect, generate an electrical voltage in the open ends of two conductors connected to one another in the event of a temperature difference along the conductor. Devices for generating energy from offgas heat are known and are disclosed, for example, in DE 10 2008 005 334 A1.

According to the process employed, offgas has temperatures between 200° C. and 1000° C. Materials used to date for thermoelectric generators, for example bismuth, telluride or lead telluride, do not tolerate these high temperatures and therefore either have to be insulated from the heat, require provision of a bypass, which diverts the offgas as soon as the offgas temperature becomes too high for the materials used. Both mean increased costs as a result of the incorporation of valves, bypass pipes, etc., increased power consumption as a result of additional elements, and measuring and regulating devices and prolonged installation times.

The greater the temperature gradient across a thermoelectric generator, the greater the efficiency thereof. Both insulation and a bypass have the additional disadvantage that a considerable portion of the heat is released to the environment with no possibility of utilization.

It is therefore an object of the invention to provide a thermoelectric generator comprising at least one pipe which conducts a hot medium and at least one thermoelectric module which can function fully even at high temperatures and nevertheless has high efficiency.

The object is achieved by a thermoelectric generator comprising at least one pipe which conducts a hot medium, and comprising at least one thermoelectric module, wherein the thermoelectric generator comprises at least one layer of a phase change material (PCM). In the present context, a layer of a phase change material means either one layer only of the at least one phase change material, or alternatively an alloy which comprises at least one phase change material.

This layer is preferably mounted between the pipe, for example an offgas pipe conducting a hot offgas stream, and the thermoelectric module. Likewise in the context of the present invention, the layer can be configured as an outer shell, for example an encapsulation, around the thermoelectric generator.

Another possible configuration of the solution proposed in accordance with the invention is to embed the at least one thermoelectric module of the thermoelectric generator into the layer or several layers of phase change material.

Phase change materials have the property of being able to regulate the temperature of their environment by storing heat. From a temperature T_{X} adjustable by the production process, the material begins to melt and absorbs a large amount of heat as a result of its high heat of fusion. Provided that the entire phase change material has not melted, the temperature in the environment of the phase change material does not rise.

Excess heat Q_{E}, as mentioned hereinafter, represents the heat in the hot medium when it has exceeded a temperature limit T_{L} (temperature of the hot medium=T_{actual}). The at least one thermoelectric module would be exposed unprotected to this excess heat Q_{E} if there were no layer of phase change material or no alloy comprising a phase change material present to absorb this excess heat Q_{E}=dS(T_{actual}−T_{L}).

If the temperature of the hot medium rises above the temperature value T_{X}, which is preferably below the temperature limit T_{L} and which is critical for the functioning of the thermoelectric modules, there is a phase change, and this means that the phase change material melts and thus absorbs the excess heat Q_{E}. This protects the thermoelectric modules from excessively high temperatures and ensures at the same time that the excess heat Q_{E} is stored in the phase change material.

The phase change material layer stores the excess heat Q_{E} at excessively high temperatures and in this way protects the thermoelectric modules from overheating. As soon as the temperature of the hot medium falls again, the phase change material releases the heat back to the thermoelectric modules, and this has a positive effect on the efficiency of the thermoelectric generators built therefrom. At the same time, it is possible to dispense with costly and material-intensive modifications.

There exist phase change materials whose latent heat of fusion, heat of dissolution or heat of absorption is much greater than the heat that they can store on the basis of their normal specific heat capacity without the phase change effect.

The phase change material which functions as the heat storage medium is “charged” by melting, which absorbs a very large amount of heat. Since this operation is reversible, the heat storage medium releases exactly this amount of heat again on phase change from the liquid phase to the solid phase, i.e. on freezing. The advantage of this heat storage technique is based on storage of a maximum amount of heat in a minimum mass within a temperature range fixed exactly by the melting temperature of the storage material used.

The same principle can also be utilized to protect thermoelectric generators. For example, there are high-temperature phase change materials or alloys. These high-temperature phase change materials or alloys can be adjusted such that they melt at a defined temperature Tₓ between 200° C. and 1000° C., and freeze again and thus store or release heat.

The layer of phase change material is arranged, for example, between a pipe which conducts the hot medium and at least one thermoelectric module, which constitute the basic units of a thermoelectric generator. This thermoelectric generator may be designed as a stand-alone system or as an integrated component.

The layer of phase change material can be formed in one piece or as at least one thin layer. It may also have been introduced over the full area or in sections, parallel or at right angles to the length of a pipe, between the thermoelectric modules and the pipe.

The layer of phase change material is preferably arranged directly or indirectly between a heat source and a hot side of the thermoelectric modules, such that the hot side of the thermoelectric modules is in turn effectively protected against overheating phenomena which otherwise occur.

In addition, the layer of phase change material can be integrated in the thermoelectric modules or in the thermoelectric generator, or applied on an inner side of the pipe, or arranged separately as an independent layer between the pipe and the thermoelectric modules.

As soon as the temperature of the hot medium falls again, the phase change material releases the heat therein back to the thermoelectric modules. This ensures that the thermoelectric modules can be operated for longer at a higher energy level, thus generating better performance and enhancing efficiency, but at the same time ruling out overheating.

The thermoelectric materials of the thermoelectric modules comprise skutterudites, semi-Heuslers, clathrates, oxides, silicides, borides, bismuth telluride and derivatives thereof, lead telluride and derivatives thereof, antimonides such as zinc antimonide and Zintl phases.

The layer of phase change material may not only be in direct contact with the pipe and the thermoelectric modules, but may also be configured as an encapsulation around the pipe and/or the thermoelectric modules. The material of the encapsulation comprises at least one pure metal, for example nickel, zirconium, titanium, silver or iron, and/or at least one metal alloy based on nickel, chromium, iron, zirconium or titanium.

The phase change materials of the layer comprise all inorganic metal salts having a melting point between 250° C. and 1700° C. Suitable metal salts comprise, for example, fluorides, chlorides, bromides, iodides, sulfates, nitrates, carbonates, chromates, molybdates, vanadates or tungstates as anions and lithium, sodium, potassium, rubidium, cesium, magnesium, calcium, strontium or barium as cation. These materials may likewise comprise all salt mixtures which form inorganic metal salts with double, triple, quadruple or quintuple eutectics.

When the layer of phase change material is configured as an alloy, the phase change material alloy comprises phase change materials as described above, and at least one metal alloy having a melting point between 200° C. and 1800° C., based on zinc, magnesium, aluminum, copper, calcium, silicon, phosphorus or antimony.

Working examples of the invention are shown in the figures and are explained in detail in the description which follows.

Heat recovery is of particular interest in motor vehicles, since the exhaust gas heat produced therein, according to the model, may be up to 35%. Effective utilization of this heat would result in a considerable improvement in the efficiency of an internal combustion engine.

For example, the layer of phase change material may have been installed at at least one position among any of the following: in an exhaust gas line, on or in an exhaust gas manifold, on or in an exhaust gas recycle pipe, on or in an exhaust gas pipe, on or in a middle silencer and/or on or in a rear silencer.

It is also possible to use the thermoelectric generator proposed in accordance with the invention in heat recovery in a power plant, for example integrated on the inside of the flues.

In addition, other fields of use of the inventive thermoelectric generator are also conceivable, for example in utilization of ambient heat for microelectronic components, geothermal power, domestic and industrial waste heat or as hybrid systems in conjunction with photovoltaic plants.

A thermoelectric generator comprising phase change material in an offgas pipe or an exhaust gas recycle line of a motor vehicle is illustrated in detail by way of example hereinafter.

The figures show:

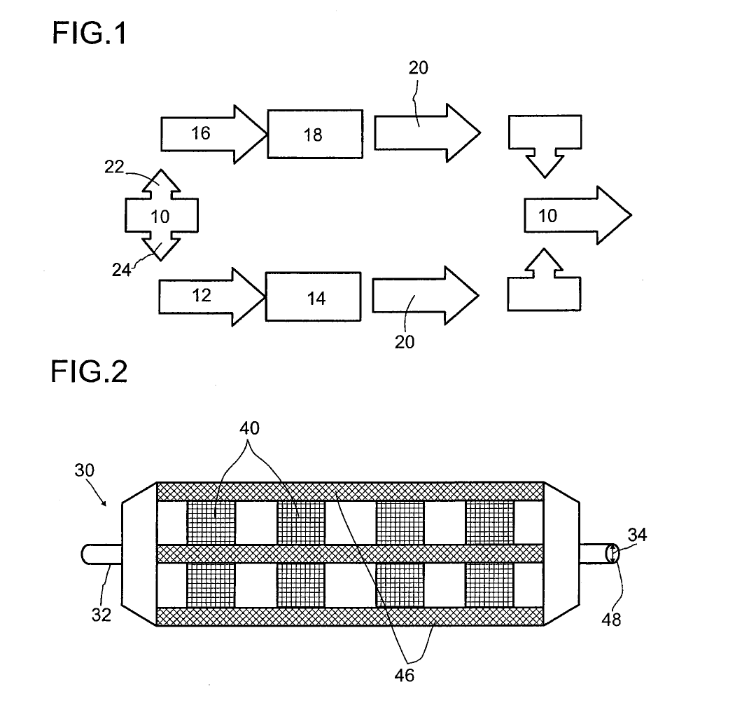

FIG. 1 a schematic structure of an offgas system with existing bypass for protection of thermoelectric modules from excessively high temperatures, and

FIG. 2 the structure of a thermoelectric generator within an exhaust gas pipe or an exhaust gas recycle pipe,

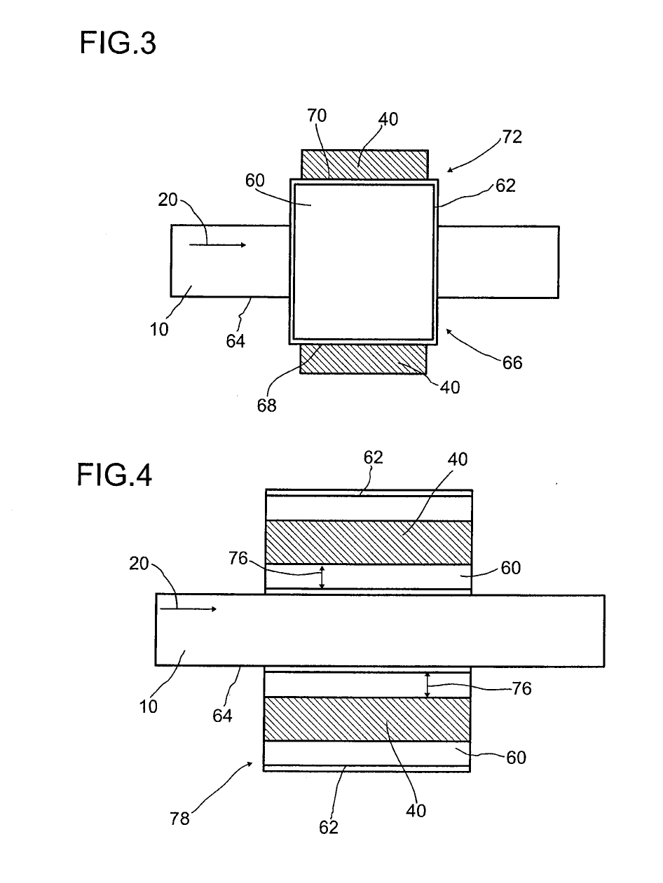

FIG. 3 a first embodiment of a phase change material and

FIG. 4 a further embodiment of an encapsulation composed of phase change material, into which at least one thermoelectric module has been introduced.

### EMBODIMENTS

In order to protect the thermoelectric module, the thermoelectric module has to date usually been insulated against excessive heat, or a bypass has been incorporated in the offgas system, and diverts the offgas stream as soon as the temperatures in the offgas become too high.

For better illustration of the invention, FIG. 1 shows the schematic structure of an offgas system with existing bypass for protection of thermoelectric modules from excessively high temperatures.

In an offgas pipe 10 with permanent temperature measurement, hot gases are present at temperature T_{actual}. To recycle a portion of the thermal energy of the gas, this gas is passed by means of a second offgas pipe 12 through one or a multitude of thermoelectric generators 14. In the course of this, the gas releases some of its heat and is then fed back at lower temperature to the offgas pipe 10.

When the temperature of the gas T_{actual} exceeds a temperature limit T_{L} which corresponds to the temperature from which the stability and functioning of the thermoelectric generator are at risk, the gas is diverted by means of a bypass pipe 16 through a valve 18, and then fed back to the offgas pipe 10. As a result of this diversion of the gas, the gas releases unutilized heat to the environment, and this heat is no longer available for power generation.

A structure of an inventive thermoelectric generator 30 integrated into a pipe 32 which conducts an offgas flow is shown in FIG. 2.

One cross section 34 of the pipe 32 is preferably round, but all other two-dimensional geometric forms are also conceivable. One length 36 of the pipe 32 is, for example, at least equal to one diameter 38 of the pipe 32. The pipe 32 is an offgas pipe or an offgas recycle pipe in a motor vehicle or a power plant.

A multitude of thermoelectric modules 40 may have been attached to an upper side of cooling lines 46. The thermoelectric modules 40 and the cooling lines 46 may be embedded into a heat exchanger or be present separately.

The thermoelectric materials of the thermoelectric modules 40 comprise skutterudites, semi-Heuslers, clathrates, oxides, silicides, borides, bismuth telluride and derivatives thereof, lead telluride and derivatives thereof, antimonides such as zinc antimonide and Zintl phases.

For example, the oxides used may be Naₓ, CaO₂, CaCo, O₉, Bi₂Sr₂, Ca₂O_{y}, Sr₂TiO₄, Sr₃Ti₂O₇, Sr₄Ti₃O₁₀, R_{1-K} H_{K}CoO₃ (R=rare earths, H=alkaline earths), Srₙ₊₁, TiₘO₃ₙ₊₁(where n=integer) YBa₂Cu₃O_{7-K}, the silicides FeSi₂, Mg₂Si, Mn₁₅Si₂₆, the borides B₄C, CaB6, the skutterudites CoSb₃; RuPdSb₆, Tx₆ (T=Co Rh, Ir; X=P, As, Sb), □₂X₈Y₂₄ where X=Co, Rh, Ir; Y=P, As, Sb, □=lanthanides, actinides, alkaline earth, alkali, hallium group IV elements,

semi-Heusler alloys, for example Tᵢ, Nᵢ, Sn; HfPdSn, and intermetallic phases, clathrates, Zn₄Sb₃, Si₈Go₁₆Ge₃₀; C₅₈Sn₄₄, Cu₄ TeSbn; and Zintl phases Yb₁₄MnSbₙ.

The thermoelectric modules 40 have a specific maximum use temperature T_{G}. If the temperature of the offgas rises above this temperature, the thermoelectric modules 40 can be damaged and lose their ability to function.

If a layer comprising a phase change material has been introduced between an inner side 48 of the pipe 32 and a hot side of a thermoelectric module 40, this layer can protect the thermoelectric modules 40 from excessively high temperatures by storing the excess heat Q_{E}.

The phase change material is selected such that the phase change material starts to melt before the maximum use temperature T_{G} of the thermoelectric modules is attained. This firstly enables compensation of excessive temperatures and protection of the thermoelectric modules 40, and the thermoelectric generator is secondly kept at a constant temperature level. This generates better performance and enhances the efficiency of the thermoelectric modules 40.

In addition, the excess heat Q_{E} stored in the phase change material is released again after the cooling of the thermoelectric generator 30, and can be converted to power by the thermoelectric modules 40. In the methods used to date for offgas heat recovery, this excess heat Q_{E} would be released to the environment without utilization and could not be utilized for power generation.

The layer of phase change material may be formed in one piece or as at least one thin layer. It may also have been introduced over the full area or in sections, parallel or at right angles to the length of the pipe 32, between the thermoelectric modules 40 and the pipe 32.

The layer of phase change material may have been integrated in the thermoelectric modules 40 or in the thermoelectric generator 30, applied on an inner side of the pipe 32 or introduced separately as an independent layer between the pipe 32 and the thermoelectric modules 40.

The layer of phase change material may have been arranged directly or indirectly between a heat source and the hot side of the thermoelectric modules 40.

In the case of direct arrangement of the phase change material it is in direct contact with the hot gas flow, whereas in the case of indirect arrangement of the phase change material the pipe wall of the offgas pipe 10 is between the hot offgas flow and the phase change material.

In the case of direct arrangement of the phase change material it is exposed directly to the hot gas flow, i.e. to the offgas flow 20, whereas in the case of indirect arrangement of the layer of phase change material the pipe wall is between the offgas flow 20, i.e. the hot gas flow, and the phase change material.

The layer of phase change material may not only be in direct contact with the pipe 32 and the thermoelectric modules 40, but also be configured as a capsule around the pipe 32 and/or the thermoelectric modules 40. The material of the capsule comprises at least one pure metal, such as nickel, zirconium, titanium, silver or iron, and/or at least one metal alloy, based on nickel, chromium, iron, zirconium or titanium.

The layer of phase change material may have been installed in any desired position(s) in an offgas line, on or in an offgas manifold, on or in an offgas recycle pipe, on or in an offgas pipe, on or in a middle silencer and/or on or in a rear silencer.

The possible phase change materials of the layer comprise all inorganic metal salts having a melting point between 250° C. and 1700° C. Suitable metal salts comprise, for example, fluorides, chlorides, bromides, iodides, sulfates, nitrates, carbonates, chromates, molybdates, vanadates or tungstates as anions and lithium, sodium, potassium, rubidium, cesium, magnesium, calcium, strontium or barium as cation.

These materials may likewise comprise all salt mixtures which form inorganic metal salts with double, triple, quadruple or quintuple eutectics.

When the layer is configured as a phase change material alloy, the phase change material alloy comprises at least one metal alloy having a melting point between 200° C. and 1800° C., based on zinc, magnesium, aluminum, copper, calcium, silicon, phosphorus or antimony.

FIG. 3 shows a first embodiment of an arrangement of the phase change material between an offgas pipe which conducts a hot medium and a thermoelectric module.

It can be inferred from the diagram in FIG. 3 that the offgas flow 20 flows in the direction of the arrow within an exhaust gas pipe 10 shown here schematically. This results in heating of an outer surface of the offgas pipe 10, on which a phase change material 60 has been applied in the form of a winding 66. The phase change material 60, which may be configured in the form of layers of thin phase change material 60 in a package 62, separates the inner side of the at least one thermoelectric module 40 from the hot side, i.e. in the present case from the outer surface 64 of the offgas pipe 10 conducting the offgas flow 20. As is evident from the diagram in FIG. 3, the underside of the at least one thermoelectric module 40 may directly adjoin an outer side 70 of the package 62, and this gives rise to a first possible arrangement 72 of the at least one thermoelectric module 40 and of the phase change material 60. On the other hand, the at least one thermoelectric module 40 may also have been embedded partly into the package 62 composed of phase change material 60 and completely or partially surround the ends of the at least one thermoelectric module 40, such that only the outer wall surface of the at least one thermoelectric module 40 remains uncovered, i.e. not surrounded, by the package 62 of phase change material 60.

Reference numeral 68 refers to an outer surface of the package 62, which surface is in contact with the inner side of the at least one thermoelectric material 40. The intermediate position of the package 62 between the outer surface 64 of the offgas pipe 10 and the inner side of the at least one thermoelectric module 40 rules out impermissible overheating thereof.

The package 62 composed of phase change material 60 serves as a heat store which starts to melt on attainment of a certain temperature and absorbs a large amount of heat owing to its capacity for heat of fusion. Unless the phase change material 60 has completely melted within the package 62, the temperature does not rise; the at least one thermoelectric module 40 can be operated at a higher energy level. On the other hand, it is ensured that the at least one thermoelectric module 40 is protected permanently from temperatures. While heat is lost in existing solutions with provision of a bypass, the solution proposed in accordance with the invention, involving the package 62 composed of phase change material, provides complete conversion of the heat therein. The heat which is bound in the form of heat of fusion on phase change from the solid to the liquid phase of the phase change material 60 is released again as soon as the temperature of the hot offgas flow 20 falls back to a temperature level which is below the melting temperature level of the phase change material 60 or with phase change material alloy. This phase change material 60 can be adapted to any geometric form of the offgas pipe 10; for example it may be round, angular, flat or cylindrical. The phase change material 60 may be in any geometric form within the package 62 according to the diagram in FIG. 3, for example as a cylinder in layer sequences, annular form and/or the like.

The diagram in FIG. 4 shows a further embodiment of an arrangement of a phase change material for protection of at least one thermoelectric module from excessively high temperatures.

In contrast to the embodiment in FIG. 3, in the embodiment in FIG. 4 the at least one thermoelectric module 40 is externally encapsulated on one side by the phase change material 60 within an encapsulation 62. Reference numeral 76 indicates the encapsulation thickness. As evident from the diagram in FIG. 4, the encapsulation thickness 76 is essentially the same on the upper and lower sides of the at least one thermoelectric module 40; however, this is not absolutely necessary, and so the encapsulation thickness 76 selected may also be higher, according to the thermal stress which occurs especially between the underside of the package 62, i.e. in the immediate proximity of the outer surface 64 and in relation to the underside of the at least one thermoelectric module 40, such that there is sufficient separation and a sufficient volume of phase change material 60 especially at this highly thermally stressed point. The diagram in FIG. 4 shows that the at least one thermoelectric module 40 is essentially completely surrounded by phase change material 60 within the package 62. The second possible arrangement, shown in FIG. 4, of the at least one thermoelectric module 40 likewise gives rise to the advantageous effects of the solution proposed in accordance with the invention, as have already been described in connection with the above embodiment of the encapsulation in FIG. 3.

The possible configuration shown in connection with FIG. 4 for a second possible arrangement 78 of the at least one thermoelectric module 40, which is part of a thermoelectric generator 30, also achieves the effect that the phase change material 60, due to its high heat storage capacity, keeps the high temperatures which arise through the hot offgas flow 20 of an outer surface 64 of the offgas pipe 10 away from the at least one thermoelectric module 40. This module can firstly be protected from overheating; secondly the operation of the at least one thermoelectric module 40 at a higher energy level is possible in the long term. According to the selection of the phase change material 60 of the package 62, it is possible to use, for example, inorganic metal salts having a melting point of between 250° C. and 1700° C., such as fluorides, chlorides, bromides, iodides, sulfates, nitrates, carbonates, chromates, molybdates, vanadates and tungstates as salts lithium, sodium, potassium, rubidium, cesium, magnesium, calcium, strontium and barium. The phase change material 60 is, for example, a salt composition of abovementioned inorganic metal salts which form double and triple eutectics, or the phase change material 60 may be configured, for example, as a salt composition of abovementioned inorganic metal salts which form quadruple or quintuple eutectics.

In addition, it is possible to use, as phase change material 60, metal alloys and combinations thereof which form double, triple, quadruple or quintuple eutectics, for example metals such as zinc, magnesium, aluminum, copper, calcium, silicon, phosphorus and antimony. The melting points of this metal alloy are between 200° C. and 1800° C.

The selection of the phase change material 60 depends to a high degree on the temperature of the offgas flow 20 which flows within the free cross section of the offgas pipe 10. For instance, exhaust gas flows 20 from self-ignition internal combustion engines may have a different temperature level than the exhaust gas flows of spark-ignition internal combustion engines or gas flows which can be utilized as process heat for use of the at least one thermoelectric module 40.

### LIST OF REFERENCE NUMERALS

10 Offgas pipe
12 Offgas pipe for the TEG
14 Thermoelectric generator (TEG)
16 Bypass pipe
18 Valve
20 Offgas flow
22 1st offgas flow
24 2nd offgas flow
30 Thermoelectric generator (TEG)
32 Pipe
34 Cross section of the pipe 32
40 Thermoelectric module (TEM)
46 Cooling lines
48 Inner side of pipe
60 Phase change material (PCM)
62 Package
64 Outer surface of offgas pipe
66 Winding of PCM around 10
68 Outer surface of package
70 Outside of package
72 1st TEM arrangement
76 Encapsulation thickness
78 2nd TEM arrangement

1. A thermoelectric generator comprising at least one pipe which conducts a hot medium, and at least one thermoelectric module, wherein the thermoelectric generator comprises at least one phase change material or at least one alloy composed of phase change material.

2. The thermoelectric generator according to claim 1, wherein the at least one thermoelectric module comprises a thermoelectric material selected from the group of the skutterudites, semi-Heuslers, clathrates, oxides, silicides, borides, bismuth telluride and derivatives thereof, lead telluride and derivatives thereof. antimonides such as zinc antimonide, and Simple phases.

3. The thermoelectric generator according to claim 1 or 2, wherein the at least one phase change material comprises at least one inorganic metal salt having a melting point between 250° C. and 1700° C.

4. The thermoelectric generator according to claim 3, wherein the at least one metal salt comprises fluorides, chlorides, bromides, iodides, sulfates, nitrates, carbonates, chromates, molybdates, vanadates or tungstates as anions, and lithium, sodium, potassium, rubidium, cesium, magnesium, calcium, strontium or barium as cation.

5. The thermoelectric generator according to any of claims 1 to 4, wherein the at least one phase change material comprises salt mixtures which form inorganic metal salts with double, triple, quadruple, or quintuple eutectics.

6. The thermoelectric generator according to any of claims 1 to 5, wherein the at least one alloy composed of phase change material comprises at least one phase change material and at least one metal alloy with a melting point between 200° C. and 1800° C., based on zinc, magnesium, aluminum, copper, calcium, silicon, phosphorus or antimony.

7. The thermoelectric generator according to any of claims 1 to 6, wherein the layer of phase change material has been introduced between a pipe and a hot side of the at least one thermoelectric module.

8. The thermoelectric generator according to any of claims 1 to 7, wherein at least one phase change material or at least one alloy composed of phase change material has been integrated in the thermoelectric modules or in the thermoelectric generator, or applied on an inner side of the pipe, or introduced separately between the pipe and the at least one thermoelectric module.

9. The thermoelectric generator according to any of claims 1 to 8, wherein the at least one phase change material or at least one alloy composed of phase change material has been introduced over the full area or in sections, parallel or at right angles to the length of the pipe between the at least one thermoelectric module and the pipe.

10. The thermoelectric generator according to any of claims 1 to 9, wherein at least one phase change material or at least one alloy composed of phase change material has been inserted directly or indirectly between a heat source and the hot side of the thermoelectric modules.

11. The thermoelectric generator according to any of claims 1 to 10, wherein the at least one phase change material or at least one alloy composed of phase change material has been formed in one piece or as at least one thin layer.

12. The thermoelectric generator according to any of claims 1 to 11, wherein the phase change material or at least one alloy composed of phase change material has been formed as an encapsulation around the pipe and/or the at least one thermoelectric module, in which case a package comprises at least one pure metal, such as nickel, zirconium, titanium, silver or iron, and/or at least one metal alloy based on nickel, chromium, iron, zirconium or titanium.

13. The thermoelectric generator according to any of claims 1 to 12, wherein the at least one phase change material or at least one alloy composed of phase change material has been installed at any position in an offgas line, on or in a manifold, on or in an offgas recycle pipe, on or in an offgas pipe, on or in a silencer or on and/or in a rear silencer.

14. The thermoelectric generator according to any of claims 1 to 13, wherein the thermoelectric generator is used in a motor vehicle.

15. The thermoelectric generator according to claims 1-14, wherein the thermoelectric generator is used in a power plant.

16. The thermoelectric generator according to any of the preceding claims, wherein a heat exchanger which is present in the offgas pipe and through which the offgas flows, has an encapsulation or a package of at least one phase change material applied thereon, and protects at least one thermoelectric module of a thermoelectric generator from overheating.

17. The thermoelectric generator according to one or more of the preceding claims, wherein the at least one phase change material or an alloy which comprises at least one phase change material is present in a package, which has been applied either on an outer surface of a pipe through which hot offgas flows, or which surrounds the at least one thermoelectric module.

18. The thermoelectric generator according to one or more of the preceding claims, wherein an encapsulation thickness within a package of phase change material is constant in relation to embedding of the at least one thermoelectric module, or the encapsulation thickness especially between an outer surface of the offgas pipe which conducts the hot offgas flow and the inside of the at least one thermoelectric module, is greater.

19. A process for producing a thermoelectric generator according to one or more of claims 1 to 13, in which a phase change material or at least one alloy composed of phase change material according to one or more of claims 3 to 6 has been introduced between an outer surface of a pipe which conducts hot medium and a hot side of a thermoelectric module.
